(19) United States
(12) Patent Application Publication
(10) Pub. No.: US 2005/0121072 A1
(43) Pub. Date: Jun. 9, 2005

(54) Portable Garden Power Supply with Solar Panel

(76) Inventor: Ed Stengel, Kemble (CA)

Correspondence Address: MARKS & CLERK, P.O. BOX 957, STATION B, OTTAWA, ON, K1P 5S7, CA

(21) Appl. No.: 10/707,311

(22) Filed: Dec. 4, 2003

(51) Int. Cl. H01L 31/00

(52) U.S. Cl. 136/291; 136/244

(57) ABSTRACT

A portable garden power supply, including a massive body having a base for setting on the ground so that said body maintains a stable position, said body having an appearance resembling a natural garden feature, an inclined solar electricity-producing array exposed on a surface portion of the massive body to generate an electrical current, and a power outlet located on the massive body for providing power from the solar panel to power a small electrical pump or garden accessory.

### BACKGROUND OF INVENTION

This invention relates to the field of garden accessories, and in particular to a power supply for powering garden fountains, lights and the like.

Many avid gardeners like to incorporate water features or accent lights into their gardens. Such features often include small fountains, bird baths, waterfalls and the like that are driven by small electrical pumps. These pumps require a power supply, and usually this is provided by the mains supply. This means that an electrical cable must be taken to the site of the electrical pump from the nearest source of electrical power, which can often be some distance away. The electrical cable is unsightly and usually must be hidden by digging of a trench to bury it. In some cases, the water feature may be located too far from a mains supply to make it feasible to provide electrical power at all.

Since these features are often in continuous operation, the cost of running them can be significant over a period of time.

Alternative energy sources are available, but any alternative source must not destroy the visual appearance of the landscape. Avid gardeners can be very particular about artificial devices that intrude on the aesthetic appearance of their landscaping.

### SUMMARY OF INVENTION

The present invention provides a portable garden power supply with a solar panel disguised as a natural feature, such as a rock. The power supply preferably incorporates a rechargeable battery that is recharged by the solar panel during daylight hours to permit operation at night or during periods of insufficient light.

According to the present invention there is provided a portable garden power supply, comprising a massive body having a base for setting on the ground so that said body maintains a stable position, said body having an appearance resembling a natural garden feature; an inclined solar electricity-producing array exposed on a surface portion of said massive body to generate an electrical current; and a power outlet for providing power from said solar panel to power a small electrical pump or garden accessory.

The massive body is typically disguised as a garden rock, although it could take on other natural forms, such as a small tree stump. Generally, it will serve to disguise the function of the device as a power supply. The body can be made of hollowed out natural rock, or colored plastic, clay or other suitable material.

### BRIEF DESCRIPTION OF DRAWINGS

The invention will now be described in more detail, by way of example only, with reference to the accompanying drawings, in which:

FIG. 1 is a perspective view of a portable garden power supply in accordance with one embodiment of the invention; and

FIG. 2 is a circuit diagram showing the electrical configuration.

### DETAILED DESCRIPTION

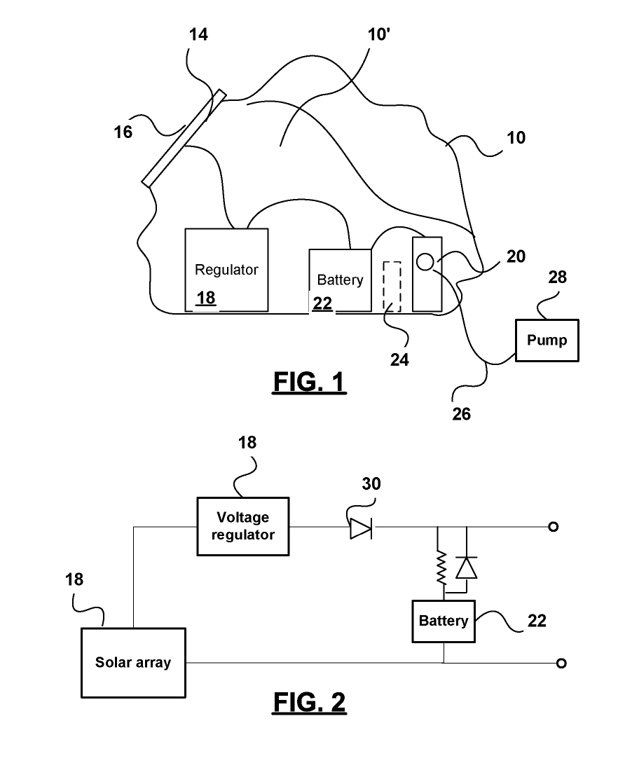

The power supply shown in FIG. 1 comprises a massive body 10, weighing approximately 5 lbs, in the shape of a small rock, such as is typically found in the garden. The rock can for example be made of granite. The size would typically be 8 in. wide×7 in. deep×7 in. high, although any size of rock that is sufficient to support the solar panel and at the same time look inconspicuous will suffice.

The massive body should have sufficient weight to enable it to be set firmly on the ground without risk of it blowing away or being easily knocked over, yet it should be sufficiently light to be conveniently moved by a gardener without the need for lifting equipment. The body can be made out of a natural rock, or alternatively from a plastic imitation molded to look like a rock. In this embodiment it will be assumed that the rock is natural. If the body is synthetic, it can be of hollow plastic for example, in which case either weights or other internal components, such as a battery, can be used to weight it sufficiently to prevent it from blowing around.

The exposed part of the body 10 has an irregular shape 12 and forms a natural feature that would be expected to be found in a garden, such as a rock in this case, so that it can be placed next to a powered garden feature, such as a fountain, without appearing out of place or spoiling the visual appearance of the feature.

The base 12 of the body 10 is generally flat so that the body can be set on the ground in such a way that it remains in a stable position. The base can be formed by cutting through a natural rock with a saw.

The upper portion of the body 10 has an upwardly angled flat surface 14 so that it can be directed toward the sun. At temperature latitudes, around 45°, this would typically be set at an angle of about 45°, which would be the median elevation of the sun. The flat surface 14 can be formed in the same way as the base, namely by slicing off a portion of the rock.

The angled surface 14 supports a solid state solar array 16, in the form of a panel, which is permanently affixed to the surface 14, for example, by gluing. Such panels are commercially available. A suitable panel is manufactured by Siemens. Another suitable panel is made by Photon Technologies of Severna Park, Md. A solar panel is described in U.S. Pat. No. 5,793,184, the contents of which are incorporated herein by reference.

The solar panel 16 is connected to an optional regulator 18 located inside the massive body 10. In the case of a natural rock this can be hollowed out to receive the regulator and other equipment, although in the case of a synthetic rock the body could of course be hollow to start with. The optional regulator controls the voltage and this is provided to outlet 20 located on the side of the body 10. The outlet 20 provides a low voltage DC current for powering small DC powered devices, for example 12V devices. The outlet 20 can include a number of different output jacks so as to power a number of devices and also possibly to provide different voltages. Or one output jack may provide an ac and another may provide a dc voltage.

In the example shown the outlet 20 provides power through cord 26 to a small pump 28. Since the generator can be placed close to the pump 28 in view of its inconspicuous nature, the cord 26 can be made short (less than 3 ft.)A block diagram of one embodiment employing the regulator 18 and battery 22 is shown in FIG. 2. The voltage regulator charges the battery 22 through diode 20 to prevent the battery from discharging back through the solar array 18.

In certain applications, such as small pump applications, the regulator is not necessary. The device outputs a variable voltage depending on the amount of sunlight, and the pump output fluctuates accordingly. However, in some applications this is not important.

In a preferred embodiment, the solar panel 16 supplies power to a rechargeable battery, such as a lead-acid battery 22, although other types of rechargeable batter, such as NiCad, could be employed. The battery permits the device to operate after dark, and is essential if the device is to be used to power small garden accent lights, for example.

If desired, an inverter can be included in the body 10 so as to provide low wattage AC power. This can be useful, for example, for powering small fluorescent lights, or small mains powered pumps.

The power supply can be conveniently used in a garden setting to permit the operation of small electrical devices without the need for connection to a mains supply, and without spoiling the landscape design. The power supply has the added advantage that the source of electricity is free, environmentally friendly, and since it has no moving parts requires little maintenance.

1. A portable garden power supply, comprising: a massive body having a base for setting on the ground so that said body maintains a stable position, said body having an appearance resembling a natural garden feature; an inclined solar electricity-producing array exposed on a surface portion of said massive body to generate an electrical current; and a power outlet for providing power from said solar panel to power a small electrical pump or garden accessory.

2. A portable garden power supply as claimed in claim 1, wherein said massive body is at least partly hollow and a regulator is located in said massive body for regulating the voltage at said power outlet.

3. A portable garden power supply as claimed in claim 2, further comprising a rechargeable battery located in said massive body, said rechargeable battery being charged by said solar panel.

4. A portable garden power supply as claimed in claim 1, wherein said massive body is in the shape of a rock.

5. A portable garden power supply as claimed in claim 1, wherein said inclined solar electricity-producing panel is angled upwardly at an angle of about 45°.

6. A portable garden power supply as claimed in claim 1, further comprising an inverter in said massive body for generating ac current.

7. A portable garden power supply as claimed in claim 1, wherein said base is flat on its underside to provide a stable surface for setting on the ground.

8. A portable garden power supply as claimed in claim 1, wherein said massive body is formed from a natural rock.

9. A portable garden power supply as claimed in claim 3, wherein said massive body is formed from a natural rock hollowed out to accommodate said rechargeable battery.

10. A portable garden power supply as claimed in claim 1, wherein massive body is formed from synthetic material shaped to resemble a natural rock.

11. A portable garden power supply as claimed in claim 10, wherein said massive body is made of plastic.

12. A portable garden power supply as claimed in claim 3, comprising a plurality of output jacks providing a plurality of power outlets at the same or different voltages.

13. A portable garden power supply as claimed in claim 1, wherein said surface portion is flat.
